(19) United States
(12) Patent Application Publication
(10) Pub. No.: US 2025/0233380 A1
(43) Pub. Date: Jul. 17, 2025

(54) GAS LASER DEVICE AND ELECTRONIC DEVICE MANUFACTURING METHOD

(71) Applicant: Gigaphoton Inc., Tochigi (JP)

(72) Inventor: Junichi MAEKAWA, Oyama-shi (JP)

(73) Assignee: Gigaphoton Inc., Tochigi (JP)

(21) Appl. No.: 19/098,316

(22) Filed: Apr. 2, 2025

Related U.S. Application Data
(63) Continuation of application No. PCT/JP2022/041946, filed on Nov. 10, 2022.

(51) Int. Cl. H01S 3/105; H01S 3/225

(52) U.S. Cl. CPC H01S 3/105; H01S 3/2251

(57) ABSTRACT

A gas laser device includes a chamber device including an electrode inside the chamber device in which a laser gas is sealed and configured to output, to outside through a window, light generated from the laser gas by a voltage being applied to the electrode, a mirror disposed outside the chamber device and configured to reflect a part of the light output from the chamber device, a holding portion holding the mirror and configured to be movable in a predetermined direction perpendicular to an optical axis of the light, a frame member configured to be movable in the predetermined direction and including an opening from which the mirror is exposed, a moving mechanism configured to cause the frame member to move, and an elastic connecting portion configured to connect the holding portion and the frame member with an elastic force.

### CROSS-REFERENCE TO RELATED APPLICATIONS

The present application is a continuation application of International Application No. PCT/JP2022/041946, filed on Nov. 10, 2022, the entire contents of which are hereby incorporated by reference.

### BACKGROUND

### 1. Technical Field

The present disclosure relates to a gas laser device and an electronic device manufacturing method.

### 2. Related Art

Recently, an improvement in resolution in semiconductor exposure devices has been desired with miniaturization and high integration of semiconductor integrated circuits. For this purpose, exposure light sources that emit light having shorter wavelengths have been developed. For example, a KrF excimer laser device that outputs laser light having a wavelength of about 248.0 nm and an ArF excimer laser device that outputs laser light having a wavelength of about 193.4 nm are used as gas laser devices for exposure.

The KrF excimer laser device and the ArF excimer laser device each have a spectral line width that is as large as 350 pm to 400 pm in spontaneous oscillation light. Therefore, when a projection lens is formed of a material that transmits ultraviolet rays such as KrF and ArF laser light, chromatic aberration may occur. As a result, the resolution may decrease. Thus, it is necessary to narrow a spectral line width of laser light output from a gas laser device to the extent that the chromatic aberration can be ignored. For this purpose, a line narrowing module (LNM) including a line narrowing element (etalon, grating, and the like) may be provided in a laser resonator of the gas laser device to narrow the spectral line width. In the following description, a gas laser device with a narrowed spectral line width will be referred to as a line-narrowed gas laser device.

### LIST OF DOCUMENTS

### Patent Documents

Patent Document 1: Japanese Patent Laid-Open No. 11-330592
Patent Document 2: Japanese Patent Laid-Open No. 6-224498
Patent Document 3: Specification of U.S. Pat. No. 6,792,014

### SUMMARY

A gas laser device according to an aspect of the present disclosure may include a chamber device including an electrode inside the chamber device in which a laser gas is sealed, the chamber device being configured to output, to outside through a window, light generated from the laser gas by a voltage being applied to the electrode, a mirror disposed outside the chamber device and configured to reflect a part of the light output from the chamber device, a holding portion holding the mirror and configured to be movable in a predetermined direction perpendicular to an optical axis of the light, a frame member configured to be movable in the predetermined direction and including an opening from which the mirror is exposed, a moving mechanism configured to cause the frame member to move, and an elastic connecting portion configured to connect the holding portion and the frame member with an elastic force.

An electronic device manufacturing method according to an aspect of the present disclosure may include generating laser light with a gas laser device, the gas laser device including a chamber device including an electrode inside the chamber device in which laser gas is sealed, the chamber device being configured to output, to outside through a window, light generated from the laser gas by a voltage being applied to the electrode, a mirror disposed outside the chamber device and configured to reflect a part of the light output through the window, a holding portion holding the mirror and configured to be movable in a predetermined direction perpendicular to an optical axis of the light, a frame member configured to be movable in the predetermined direction and including an opening from which the mirror is exposed, a moving mechanism configured to cause the frame member to move, and an elastic connecting portion configured to connect the holding portion and the frame member with an elastic force, outputting the laser light to an exposure device, and exposing a photosensitive substrate to the laser light inside the exposure device to manufacture an electronic device.

### BRIEF DESCRIPTION OF THE DRAWINGS

Several embodiments of the present disclosure will be described below merely as examples with reference to the accompanying drawings.

FIG. 1 is a schematic view illustrating an overview configuration example of an entire electronic device manufacturing apparatus.

FIG. 2 is a schematic view illustrating an overview configuration example of an entire gas laser device of a comparative example.

FIG. 3 is a front view of an output-side holding unit of the comparative example.

FIG. 4 is a sectional view of the output-side holding unit illustrated in FIG. 3 taken along the line IV-IV.

FIG. 5 is a sectional view of the output-side holding unit illustrated in FIG. 3 taken along the line V-V.

FIG. 6 is a front view of an output coupling mirror.

FIG. 7 is a front view of an output-side holding unit of a first embodiment.

FIG. 8 is a sectional view of the output-side holding unit illustrated in FIG. 7 taken along the line VIII-VIII.

FIG. 9 is a sectional view of the output-side holding unit illustrated in FIG. 7 taken along the line IX-IX.

FIG. 10 is a diagram illustrating a state where an angle of a holding portion has been adjusted.

FIG. 11 is a front view of an output-side holding unit of a second embodiment.

FIG. 12 is a sectional view of the output-side holding unit illustrated in FIG. 11 taken along the line XII-XII.

FIG. 13 is a sectional view of the output-side holding unit illustrated in FIG. 11 taken along the line XIII-XIII.

FIG. 14 is a front view of an output-side holding unit of a third embodiment.

FIG. 15 is a sectional view of the output-side holding unit illustrated in FIG. 14 taken along the line XV-XV.

### DESCRIPTION OF EMBODIMENTS

1. Description of Electronic Device Manufacturing Apparatus Used in Exposure Process for Electronic Device
2. Description of Gas Laser Device of Comparative Example
   2.1 Configuration
   2.2 Operation
   2.3 Problem
3. Description of Gas Laser Device of First Embodiment
   3.1 Configuration
   3.2 Operation
   3.3 Effect and Advantage
4. Description of Gas Laser Device of Second Embodiment
   4.1 Configuration
   4.2 Operation
   4.3 Effect and Advantage
5. Description of Gas Laser Device of Third Embodiment
   5.1 Configuration
   5.2 Operation
   5.3 Effect and Advantage

Hereinafter, embodiments of the present disclosure will be described in detail with reference to the drawings. The embodiments described below illustrate some examples of the present disclosure and are not intended to limit content of the present disclosure. Also, all configurations and operations described in the embodiments are not necessarily essential as configurations and operations of the present disclosure. Note that the same components will be denoted by the same reference signs and repeated description will be omitted.

### 1. Description of Electronic Device Manufacturing Apparatus Used in Exposure Process for Electronic Device

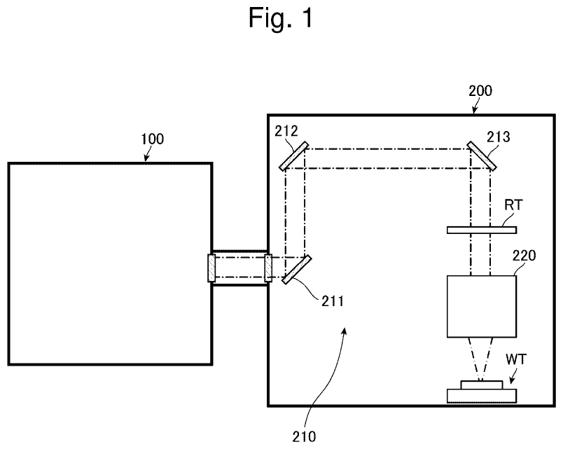

FIG. 1 is a schematic view illustrating an overview configuration example of an entire electronic device manufacturing apparatus used in an exposure process for an electronic device. As illustrated in FIG. 1, the manufacturing apparatus used in the exposure process includes a gas laser device 100 and an exposure device 200. The exposure device 200 includes an illumination optical system 210 including a plurality of mirrors 211, 212, and 213 and a projection optical system 220. The illumination optical system 210 illuminates a reticle pattern of a reticle stage RT with laser light incident from the gas laser device 100. The projection optical system 220 projects the laser light transmitted through the reticle with a reduced size and causes an image of the laser light to be formed on an unillustrated workpiece which is disposed on a workpiece table WT. The workpiece is a photosensitive substrate such as a semiconductor wafer to which photoresist is applied. The exposure device 200 synchronously translates the reticle stage RT and the workpiece table WT to thereby expose the workpiece to the laser light reflecting the reticle pattern. It is possible to manufacture a semiconductor device which is an electronic device by transferring a device pattern to a semiconductor wafer in the exposure process as described above.

### 2. Description of Gas Laser Device of Comparative Example

### 2.1 Configuration

A gas laser device of a comparative example will be described. Note that the comparative example of the present disclosure is a mode recognized by the applicant as known only by the applicant and is not an example recognized by the applicant as being publicly known.

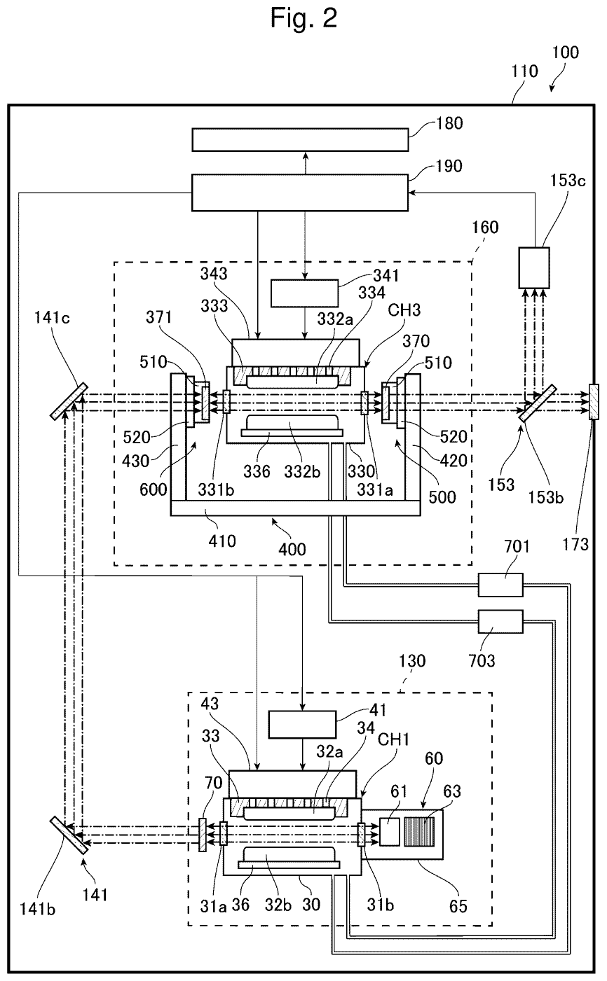

FIG. 2 is a schematic view illustrating an overview configuration example of the entire gas laser device 100 of this example. The gas laser device 100 is, for example, an ArF excimer laser device using mixed gas containing argon (Ar), fluorine (F2), and neon (Ne). The gas laser device 100 outputs laser light having a center wavelength of about 193.4 nm. Note that the gas laser device 100 may be a gas laser device other than the ArF excimer laser device and may be, for example, a KrF excimer laser device using mixed gas containing krypton (Kr), F₂, and Ne. In this case, the gas laser device 100 outputs laser light having a center wavelength of about 248.0 nm. The mixed gas containing Ar, F₂, and Ne which is a laser medium and the mixed gas containing Kr, F₂, and Ne which is a laser medium may be referred to as laser gas. Note that in the mixed gas used in each of the ArF excimer laser device and the KrF excimer laser device, helium (He) may be used instead of Ne.

The gas laser device 100 of this example mainly includes a housing 110, a laser oscillator 130 that is a master oscillator disposed in an internal space of the housing 110, a light transmission unit 141, an amplifier 160 that is a power oscillator, a detection section 153, a display section 180, a processor 190, a laser gas exhaust device 701, and a laser gas supply device 703.

The laser oscillator 130 mainly includes a chamber device CH1, a charger 41, a pulse power module 43, a line narrowing module 60, and an output coupling mirror 70.

In FIG. 2, an internal configuration of the chamber device CH1 seen in a direction substantially perpendicular to a traveling direction of the laser light is illustrated. The chamber device CH1 mainly includes a housing 30, a pair of windows 31a and 31b, a pair of electrodes 32a and 32b, an insulating portion 33, a feedthrough 34, and an electrode holder portion 36.

The laser gas is supplied from the laser gas supply device 703 to the internal space of the housing 30 via a pipe, and the internal space of the housing 30 is filled with the laser gas. The internal space is a space in which light is generated by excitation of the laser medium in the laser gas. The light travels to the windows 31a and 31b.

The window 31a is disposed in a wall surface of the housing 30 on the front side in the traveling direction of the laser light from the gas laser device 100 to the exposure device 200, and the window 31b is disposed in a wall surface of the housing 30 on the rear side in the traveling direction. The windows 31a and 31b are inclined at the Brewster angle with respect to the traveling direction of the laser light such that reflection of P-polarized light of the laser light is suppressed. The output surfaces of the windows 31a and 31b are flat surfaces.

The electrodes 32a and 32b are disposed to face each other in the internal space of the housing 30, and the longitudinal direction of the electrodes 32a and 32b follows the traveling direction of the light generated by a high voltage applied between the electrode 32a and the electrode 32b. The window 31a and the window 31b are positioned on the respective sides across a space between the electrode 32a and the electrode 32b in the housing 30. The electrodes 32a and 32b are discharge electrodes for exciting the laser medium by glow discharge. In this example, the electrode 32a is a cathode, and the electrode 32b is an anode.

The electrode 32a is supported by the insulating portion 33. The insulating portion 33 closes an opening formed in the housing 30. The insulating portion 33 includes an insulator. Furthermore, the feedthrough 34 composed of a conductive member is disposed in the insulating portion 33. The feedthrough 34 applies, to the electrode 32a, a voltage supplied from the pulse power module 43. The electrode 32b is supported by the electrode holder portion 36 and is electrically connected to the electrode holder portion 36.

The charger 41 is a DC power source device that charges, with a predetermined voltage, an unillustrated capacitor which is provided inside the pulse power module 43. The charger 41 is disposed outside the housing 30 and is connected to the pulse power module 43. The pulse power module 43 includes an unillustrated switch which is controlled by the processor 190. The pulse power module 43 is a voltage application circuit that, when the switch is turned from OFF to ON through the control, boosts the voltage applied from the charger 41 to generate a pulsed high voltage and applies the high voltage to the electrodes 32a and 32b. When the high voltage is applied, discharge occurs between the electrode 32a and the electrode 32b. Energy of the discharge excites the laser medium inside the housing 30. When the excited laser gas shifts to a ground level, light is emitted, and the emitted light is transmitted through the windows 31a and 31b and is output to the outside of the housing 30.

The line narrowing module 60 includes a housing 65, a prism 61 disposed in an internal space of the housing 65, a grating 63, and an unillustrated rotation stage. An opening is formed in the housing 65, and the housing 65 is connected to the housing 30 on the rear side via the opening.

The prism 61 expands the beam width of the light output through the window 31b and causes the light to be incident on the grating 63. Also, the prism 61 reduces the beam width of light reflected from the grating 63 and returns the light to the internal space of the housing 30 through the window 31b. The prism 61 is supported by the rotation stage and is rotated by the rotation stage. The incident angle of the light on the grating 63 is changed by the rotation of the prism 61. Therefore, the wavelength of the light returning from the grating 63 to the housing 30 via the prism 61 can be selected by rotation of the prism 61. Although FIG. 2 illustrates an example in which one prism 61 is disposed, two or more prisms may be disposed.

The surface of the grating 63 is formed of a material having high reflectance, and a large number of grooves are provided in the surface at predetermined intervals. The grating 63 is a dispersive optical element. The sectional shape of each groove is, for example, a right triangle. The light incident on the grating 63 from the prism 61 is reflected by these grooves and is diffracted in a direction in accordance with the wavelength of the light. The grating 63 is disposed in the Littrow arrangement such that the incident angle of the light incident on the grating 63 from the prism 61 coincides with the diffraction angle of diffracted light having a desired wavelength. Thus, light with a desired wavelength is returned to the housing 30 via the prism 61.

The output coupling mirror 70 faces the window 31a, transmits a part of the laser light output through the window 31a, and reflects the other part thereof to return the other part to the internal space of the housing 30 through the window 31a. The output coupling mirror 70 is fixed to an unillustrated holder and is disposed in the internal space of the housing 110.

The grating 63 and the output coupling mirror 70 provided on the respective sides across the housing 30 configure a Fabry-Perot resonator, and the housing 30 is disposed on an optical path of the resonator.

The light transmission unit 141 mainly includes high reflective mirrors 141b and 141c. The high reflective mirrors 141b and 141c are fixed to respective unillustrated holders with their inclination angles adjusted, and are disposed in the internal space of the housing 110. The high reflective mirrors 141b and 141c highly reflect the laser light. The high reflective mirrors 141b and 141c are disposed on the optical path of the laser light from the output coupling mirror 70. The laser light is reflected by the high reflective mirrors 141b and 141c and travels to a rear mirror 371 of the amplifier 160. At least a part of the laser light is transmitted through the rear mirror 371.

The amplifier 160 amplifies the energy of the laser light output from the laser oscillator 130. A basic configuration of the amplifier 160 is substantially the same as that of the laser oscillator 130. In order to separate the components of the amplifier 160 from the components of the laser oscillator 130, the chamber device, the housing, the pair of windows, the pair of electrodes, the insulating portion, the feedthrough, the electrode holder portion, the charger, the pulse power module, and the output coupling mirror of the amplifier 160 will be described as a chamber device CH3, a housing 330, a pair of windows 331a and 331b, a pair of electrodes 332a and 332b, an insulating portion 333, a feedthrough 334, an electrode holder portion 336, a charger 341, a pulse power module 343, and an output coupling mirror 370. The electrodes 332a and 332b cause discharge for amplifying the laser light from the laser oscillator 130. The pulse power module 343 is a voltage application circuit similar to the pulse power module 43.

Furthermore, the amplifier 160 is different from the laser oscillator 130 in that the line narrowing module 60 is not included and the rear mirror 371, a support member 400, an output-side holding unit 500, and a rear-side holding unit 600 are included.

The rear mirror 371 is provided between the high reflective mirror 141c and the window 331b and faces to each of them. The rear mirror 371 transmits a part of the laser light from the laser oscillator 130 toward a space between the electrodes 332a and 332b and reflects a part of the laser light amplified by the electrodes 332a and 332b toward the space between the electrodes 332a and 332b.

The output coupling mirror 370 is provided between the window 331a and a beam splitter 153b and faces to each of them. The output coupling mirror 370 reflects a part of the laser light amplified by the electrodes 332a and 332b and then output toward the space between the electrodes 332a and 332b, and transmits the other part of the laser light toward the detection section 153. For this purpose, the surface of the output coupling mirror 370 facing the window 331a is coated with a partial reflective film having predetermined reflectance. Hereinafter, a surface on the side facing the chamber device CH3 will be referred to as a main surface in description of each member. In the output coupling mirror 370, a surface coated with the partially reflective film is defined as a main surface.

The output coupling mirror 370 has a circular shape. The surface of the output coupling mirror 370 facing the window 331a and the surface opposed to the surface are flat surfaces. The rear mirror 371 and the output coupling mirror 70 have configurations similar to that of the output coupling mirror 370.

The rear mirror 371 and the output coupling mirror 370 provided on the respective sides across the housing 330 configure a resonator with which the laser light amplified by the electrodes 332a and 332b resonates. The housing 330 is disposed on an optical path of the resonator, and the laser light amplified and output from the housing 330 reciprocates between the rear mirror 371 and the output coupling mirror 370. The reciprocating laser light is amplified every time the laser light passes through a laser gain space between the electrode 332a and the electrode 332b. A part of the amplified laser light is transmitted through the output coupling mirror 370.

The support member 400 includes a bottom plate member 410, an output-side support member 420, and a rear-side support member 430. The bottom plate member 410 is a flat plate that is longer than the housing 330 and extends in the traveling direction of the laser light. One end of the bottom plate member 410 is located closer to the side of the beam splitter 153b, which will be described later, of the detection section 153 than the window 331a, and the other end is located closer to the side of the high reflective mirror 141c than the window 331b. The output-side support member 420 is perpendicularly connected to the bottom plate member 410 at the one end of the bottom plate member 410, and the rear-side support member 430 is perpendicularly connected to the bottom plate member 410 at the other end of the bottom plate member 410. The output-side support member 420 and the rear-side support member 430 are plate-shaped members and extend to positions where they overlap the window 331a and the window 331b, respectively.

The output-side holding unit 500 is disposed in the output-side support member 420 and holds the output coupling mirror 370. The rear-side holding unit 600 is disposed in the rear-side support member 430 and holds the rear mirror 371. The output coupling mirror 370 is disposed between the window 331a and the beam splitter 153b, and the rear mirror 371 is disposed between the window 331b and the high reflective mirror 141c by the support member 400, the output-side holding unit 500, and the rear-side holding unit 600. Also, the output coupling mirror 370 and the rear mirror 371 are relatively positioned by the support member 400, the output-side holding unit 500, and the rear-side holding unit 600. Details of the output-side holding unit 500 and the rear-side holding unit 600 will be described later. The laser light transmitted through the output coupling mirror 370 travels to the detection section 153.

The detection section 153 mainly includes the beam splitter 153b and an optical sensor 153c.

The beam splitter 153b is disposed on the optical path of the laser light transmitted through the output coupling mirror 370. The beam splitter 153b causes the laser light transmitted through the output coupling mirror 370 to be transmitted therethrough to an outgoing window 173 at high transmittance and reflects a part of the pulse laser light toward a light receiving surface of the optical sensor 153c.

The optical sensor 153c measures pulse energy of the laser light incident on the light receiving surface of the optical sensor 153c. The optical sensor 153c is electrically connected to the processor 190 and outputs a signal indicating the measured pulse energy to the processor 190. The processor 190 controls a voltage to be applied to the electrodes 32a and 32b of the amplifier 160 on the basis of the signal.

The outgoing window 173 is provided on the side opposite to the output coupling mirror 370 with reference to the beam splitter 153b of the detection section 153. The outgoing window 173 is provided in a wall of the housing 110. The light transmitted through the beam splitter 153b is output through the outgoing window 173 to the exposure device 200 outside the housing 110. The laser light is, for example, pulse laser light having a center wavelength of 193.4 nm.

The internal spaces of the housings 30 and 330 are filled with purge gas. The purge gas includes inert gas, such as high-purity nitrogen, with reduced impurities, such as oxygen. The purge gas is supplied from an unillustrated purge gas supply source which is disposed outside the housing 110 to the internal spaces of the housings 30 and 330 through unillustrated pipes.

The display section 180 is a monitor that displays a state of control performed by the processor 190 on the basis of a signal from the processor 190.

The processor 190 of the present disclosure is a processing device including a storage device that stores a control program and a central processing unit (CPU) that executes the control program. The processor 190 is specifically configured or programmed to execute various kinds of processing included in the present disclosure. Also, the processor 190 controls the entire gas laser device 100. The processor 190 is electrically connected to an unillustrated exposure processor of the exposure device 200 and transmits and receives various signals to and from the exposure processor.

The laser gas exhaust device 701 and the laser gas supply device 703 are electrically connected to each other via the processor 190. The laser gas exhaust device 701 includes an unillustrated exhaust pump and exhausts the laser gas from the internal spaces of the housings 30 and 330 via pipes through suctioning of the exhaust pump in accordance with a control signal from the processor 190. The laser gas supply device 703 supplies the laser gas from an unillustrated laser gas supply source which is disposed outside the housing 110 to the internal spaces of the housings 30 and 330 via the pipes in accordance with a control signal from the processor 190.

Next, the output-side holding unit 500 will be described.

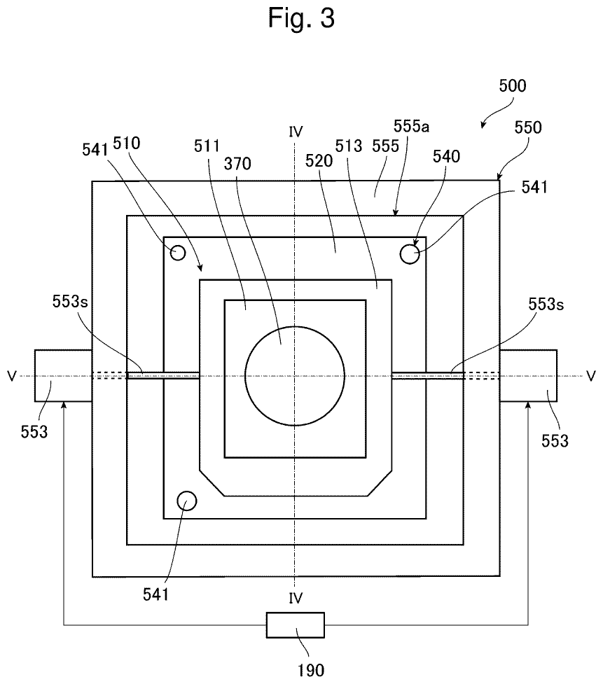

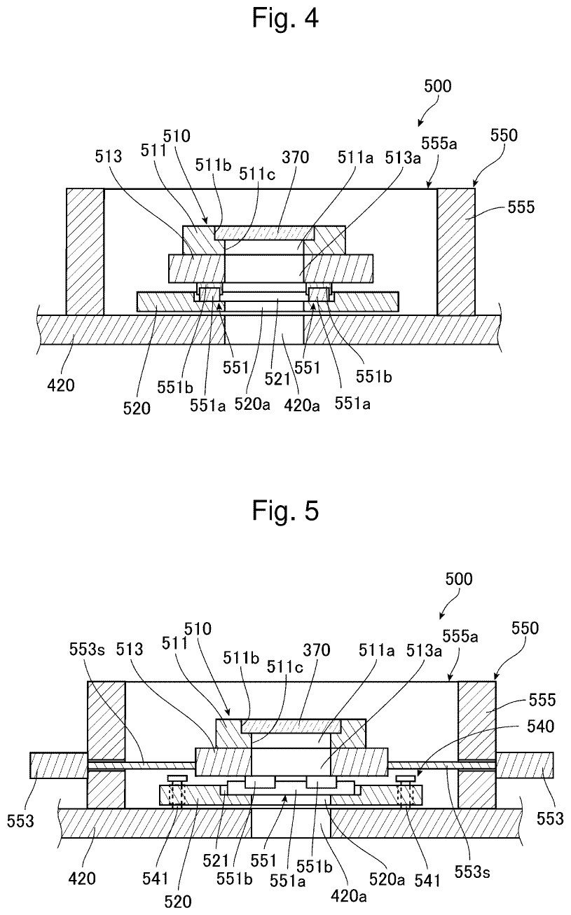

FIG. 3 is a front view of the output-side holding unit 500 of the comparative example. FIG. 4 is a sectional view of the output-side holding unit 500 illustrated in FIG. 3 taken along the line IV-IV, and FIG. 5 is a sectional view of the output-side holding unit 500 illustrated in FIG. 3 taken along the line V-V. The output-side holding unit 500 includes a holding portion 510 that holds the output coupling mirror 370, a base member 520, an angle adjusting mechanism 540, and a moving mechanism 550. Note that illustration of the output-side support member 420 is omitted in FIG. 3.

The holding portion 510 includes a main body portion 511 that holds the output coupling mirror 370 and an attachment plate 513 to which the main body portion 511 is attached. The main body portion 511 is fixed to the attachment plate 513 with unillustrated screws. Note that for the sake of clarity, the holding portion 510 is illustrated in a simplified manner and the angle adjusting mechanism 540 and the moving mechanism 550 are omitted in FIG. 2.

The main body portion 511 is provided with a through-hole 511a. The through-hole 511a includes a large-diameter portion 511b having a circular shape and a small-diameter portion 511c having a circular shape. The large-diameter portion 511b is located closer to the side of the window 331a than the small-diameter portion 511c and communicates with the small-diameter portion 511c. The diameter of the large-diameter portion 511b is larger than the diameter of the small-diameter portion 511c and has approximately the same size as the output coupling mirror 370. The output coupling mirror 370 is disposed in the large-diameter portion 511b. Light from the output coupling mirror 370 or light directed to the output coupling mirror 370 passes through the small-diameter portion 511c.

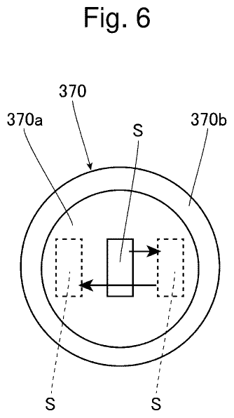

FIG. 6 is a front view of the output coupling mirror 370. An effective region 370a of the output coupling mirror 370 that overlaps the small-diameter portion 511c is a circular region irradiated with light from the window 331a. Furthermore, a non-effective region 370b is provided outside the effective region 370a in the output coupling mirror 370, and the non-effective region 370b is a ring-shaped region that overlaps a stepped surface between the large-diameter portion 511b and the small-diameter portion 511c and does not transmit light therethrough.

A part of the effective region 370a instead of the entire effective region 370a of the output coupling mirror 370 is irradiated with the light traveling from the window 331a to the output coupling mirror 370. Therefore, an irradiation spot S of the light in the effective region 370a is smaller than the effective region 370a. The shape of the irradiation spot S is formed by an unillustrated mask which is disposed between the window 331a and the output coupling mirror 370. The mask is, for example, a plate-shaped member that includes a transmission hole with a rectangular shape formed such that a part of the laser light is transmitted therethrough and that blocks the other part of the laser light. Note that the shape of the transmission hole is not limited thereto. The transmission hole is smaller than the circular effective region 370a of the output coupling mirror 370, and the irradiation spot S of the light in the effective region 370a has a rectangular shape by the laser light being transmitted through the transmission hole.

The attachment plate 513 is a plate-shaped member, and in a front view of the holding portion 510, the attachment plate 513 is larger than the main body portion 511. The attachment plate 513 is provided with a through-hole 513a similar to the small-diameter portion 511c of the through-hole 511a. The attachment plate 513 is attached to the base member 520 via the moving mechanism 550 that can cause the attachment plate 513 to move with respect to the base member 520. Details of the moving mechanism 550 will be described later. In a front view of the holding portion 510, the attachment plate 513 is smaller than the base member 520.

The base member 520 is a plate-shaped member, and the base member 520 is provided with a through-hole 520a similar to the through-hole 513a of the attachment plate 513. The base member 520 is disposed on the main surface of the output-side support member 420 via the angle adjusting mechanism 540.

The output-side support member 420 is provided with a through-hole 420a similar to the through-hole 520a of the base member 520. The main surface of the output-side support member 420 is substantially perpendicular to the optical axis of the laser light output through the window 331a and the extending direction of the support member 400. The base member 520 is disposed on the main surface of the output-side support member 420 on the side of the window 331a.

The small-diameter portion 511c of the main body portion 511, the through-hole 513a of the attachment plate 513, the through-hole 520a of the base member 520, and the through-hole 420a of the output-side support member 420 communicate with each other. The light passes through the through-holes 513a, 520a, and 420a similarly to the through-hole 511a.

The angle adjusting mechanism 540 adjusts the angle of the base member 520 with respect to the output-side support member 420 to a predetermined angle and maintains the angle. Accordingly, the angle adjusting mechanism 540 maintains the inclination angle of the holding portion 510 attached to the base member 520 via the moving mechanism 550 with respect to the output-side support member 420 at a predetermined angle. Since the output coupling mirror 370 is held by the holding portion 510 and the position of the output-side support member 420 is fixed with respect to the chamber device CH3, the angle adjusting mechanism 540 adjusts the angle of the output coupling mirror 370 to a predetermined angle with respect to the optical axis of the laser light and maintains the angle. For example, a plurality of adjustment screws 541 are used for the angle adjusting mechanism 540, the adjustment screws 541 are screwed into screw holes in the base member 520, and distal ends are engaged with the output-side support member 420. Thus, the output-side support member 420 supports the holding portion 510 via the base member 520. The angle of the base member 520 with respect to the output-side support member 420 is adjusted, and the angle of the output coupling mirror 370 with respect to the optical axis of the laser light is adjusted, through adjustment of the amount of screwing of each adjustment screw 541. The predetermined angle may be, for example, an angle at which energy of the laser light output from the gas laser device 100 is the highest. In this case, the main surfaces of the output coupling mirror 370, the attachment plate 513, and the base member 520 irradiated with the light from the window 331a are substantially perpendicular to the optical axis of the light, for example. The configuration of the angle adjusting mechanism 540 is not limited to the adjustment screws 541, and a gimbal mechanism, a kinematic mount, or the like may be used.

The moving mechanism 550 is a member capable of causing the holding portion 510 to move with respect to the output-side support member 420 in a predetermined direction perpendicular to the optical axis of the light output through the window 331a to the outside. The moving mechanism 550 includes a guide unit 551, a pair of cylinders 553, and a case 555.

The guide unit 551 guides linear movement of the holding portion 510 in the predetermined direction perpendicular to the optical axis of the laser light. The guide unit 551 in this example is a linear guide. In this example, the guide unit 551 includes rails 551a that are provided at a bottom of a groove 521 of the base member 520 and that extend in a predetermined direction and sliders 551b that are provided on the rear surface of the attachment plate 513 to straddle the rails 551a and that slide along the rails 551a. The groove 521 and the guide unit 551 are provided such that they do not overlap with the through-holes 513a and 520a. Note that for ease of understanding, the guide unit 551 that does not appear in the section is illustrated in FIG. 5.

The case 555 is disposed on the side of the main surface of the output-side support member 420 and surrounds the main body portion 511, the attachment plate 513, and the base member 520 of the output-side holding unit 500. An upper surface of the case 555 is open, and the output coupling mirror 370 is exposed from an opening 555a of the case 555 in a front view of the case 555. Therefore, the light from the window 331a is transmitted through the output coupling mirror 370 via the opening 555a. The cylinders 553 are fixed to the case 555, and shafts 553s of the cylinders 553 penetrate through the case 555.

Each of the shafts 553s of the pair of cylinders 553 extends in a predetermined direction. Distal ends of the shafts 553s are positioned on respective sides of the attachment plate 513 in the moving direction of the holding portion 510 to press the attachment plate 513 from both sides. Examples of the cylinders 553 include air cylinders. The cylinders 553 are electrically connected to the processor 190 and push and pull the attachment plate 513 through movement of the shafts 553s under control of the processor 190. Specifically, the cylinders 553 move in conjunction with each other, and the shafts 553s move in the longitudinal direction. In this case, one of the cylinders 553 pushes the attachment plate 513 via the shaft 553s and the other cylinder 553 pulls the attachment plate 513 via the shaft 553s. The amount of pushing of the one of the cylinders 553 is substantially the same as the amount of pulling of the other cylinder 553, and the amount of pushing and pulling by the cylinders 553 is the amount of movement of the holding portion 510. Note that the cylinders 553 may not be connected to the processor 190 and the attachment plate 513 may be caused to move by an operation performed by an administrator of the gas laser device 100 on the cylinders 553. The movement of the holding portion 510 by the cylinders 553 leads to movement of the output coupling mirror 370 in a predetermined direction.

The angle adjusting mechanism 540 of this example maintains the inclination angle of the holding portion 510 with respect to the output-side support member 420 at a predetermined angle regardless of the position of the holding portion 510.

The rear-side holding unit 600 has a configuration that is the same as that of the output-side holding unit 500 other than that the rear-side holding unit 600 holds the rear mirror 371 and is disposed on the main surface of the rear-side support member 430 on the side of the window 331b, and description thereof will thus be omitted. Therefore, the rear-side support member 430 is provided with a through-hole through which light passes.

### 2.2 Operation

Next, an operation of the gas laser device 100 of the comparative example will be described.

In a state before the gas laser device 100 outputs the laser light, the laser gas is supplied from the laser gas supply device 703 to the internal space of the housing 30. Furthermore, the angle adjusting mechanism 540 in the output-side holding unit 500 adjusts the inclination angle of the main surface of the output coupling mirror 370 with respect to the output-side support member 420 to a predetermined angle through the adjustment of the amount of screwing of the adjustment screws 541 and maintains this state. Similarly, the angle adjusting mechanism 540 in the rear-side holding unit 600 adjusts the inclination angle of the main surface of the rear mirror 371 with respect to the rear-side support member 430 to a predetermined angle and maintains this state.

When the gas laser device 100 outputs the laser light, the processor 190 receives a signal indicating target energy Et and a light emission trigger signal from the unillustrated exposure processor of the exposure device 200. The target energy Et is a target value of energy of the laser light used in the exposure process. The processor 190 sets a predetermined charge voltage in the charger 41 such that the energy E becomes the target energy Et, and turns on the switch of the pulse power module 43 in synchronization with the light emission trigger signal. In this manner, the pulse power module 43 generates a pulsed high voltage from the electric energy held in the charger 41, and the high voltage is applied between the electrode 32a and the electrode 32b. When the high voltage is applied, discharge occurs between the electrode 32a and the electrode 32b, the laser medium contained in the laser gas between the electrode 32a and the electrode 32b is brought into an excited state, and light is emitted when the laser medium returns to the ground state. The emitted light resonates between the grating 63 and the output coupling mirror 70, is amplified every time the light passes through the discharge space in the internal space of the housing 30, and laser oscillation occurs. A part of the laser light is transmitted through the output coupling mirror 70, is reflected by the high reflective mirrors 141b and 141c, is transmitted through the rear mirror 371 and the window 31b, and travels into the housing 330.

The processor 190 turns on the switch of the pulse power module 343 such that discharge occurs when the laser light from the laser oscillator 130 travels to the discharge space in the housing 330. The processor 190 controls the pulse power module 343 such that a high voltage is applied to the electrodes 332a and 332b after a predetermined delay time elapses from the timing at which the switch of the pulse power module 43 is turned on.

In this manner, the laser light incident on the amplifier 160 is amplified and oscillated by the amplifier 160. Furthermore, the laser light that has traveled to the internal space of the housing 330 is transmitted through the windows 331a and 331b as described above and travels to the rear mirror 371 and the output coupling mirror 370. Thus, the laser light having a predetermined wavelength reciprocates between the rear mirror 371 and the output coupling mirror 370. The laser light is amplified every time the laser light passes through the discharge space inside the housing 30, laser oscillation occurs, and a part of the laser light becomes amplified laser light.

Also, the amplified laser light from the amplifier 160 is transmitted through the output coupling mirror 370 and travels to the beam splitter 153b.

A part of the amplified laser light traveling to the beam splitter 153b is transmitted through the beam splitter 153b and the outgoing window 173 and travels to the exposure device 200, while the other part is reflected by the beam splitter 153b and travels to the optical sensor 153c.

The optical sensor 153c receives the amplified laser light and measures the energy E of the received amplified laser light. The optical sensor 153c outputs a signal indicating the measured energy E to the processor 190. The processor 190 performs feedback control on the charge voltages of the chargers 41 and 341 such that a difference ΔE between the energy E and the target energy Et falls within an allowable range. The laser light with the difference ΔE falling within the allowable range is transmitted through the beam splitter 153b and the outgoing window 173 and is then incident on the exposure device 200.

In a case where the output coupling mirror 370 is caused to move, the processor 190 brings the chargers 41 and 341 into a stopped state and brings the switches of the pulse power modules 43 and 343 into an OFF state. Therefore, the output of the light is stopped. Next, the processor 190 causes the cylinders 553 to push and pull the attachment plate 513 and causes the holding portion 510 to move in a direction perpendicular to the optical axis of the laser light output through the window 331a. In this example, the holding portion 510 moves in a direction along the short side of the rectangular irradiation spot S, that is, in the a predetermined direction perpendicular to the optical axis of the light output from the chamber device CH3. At this time, the movement direction of the holding portion 510 is guided by the guide unit 551. The movement of the holding portion 510 also leads to movement of the output coupling mirror 370. At this time, even if the holding portion 510 and the output coupling mirror 370 move, the position of the irradiation spot S does not move. Therefore, the position of the irradiation spot S moves inside the effective region 370a in the output coupling mirror 370 as indicated by the dashed line in FIG. 6. Although the predetermined direction is the direction along the short side of the rectangular irradiation spot S in this example, the predetermined direction may be a direction along the long side of the irradiation spot S. Note that, unlike FIG. 6, a part of the irradiation spot S after the movement may overlap with the irradiation spot S before the movement. After the position of the irradiation spot S moves in this manner, the gas laser device 100 operates similarly to the above description.

An operation similar to that in a case where the output coupling mirror 370 is caused to move is performed in a case where the rear mirror 371 is caused to move as well.

### 2.3 Problem

In the comparative example, the cylinders 553 are positioned on respective sides of the attachment plate 513 to press the attachment plate 513 from both sides in the moving direction of the holding portion 510. Due to the pressing force, the attachment plate 513 may be elastically deformed. There is a concern that if the attachment plate 513 is deformed, the attachment angles of the output coupling mirror 370 and the rear mirror 371 may change with respect to the optical axis of the laser light output through the window 331a, that the outgoing direction of the laser light and the output may change, and that the output laser light is not stabilized.

Thus, gas laser devices capable of stably outputting laser light will be exemplified in the following embodiments.

### 3. Description of Gas Laser Device of First Embodiment

Next, a gas laser device 100 of a first embodiment will be described. Note that configurations similar to the configurations described above will be denoted by the same reference signs, and repeated description will be omitted unless otherwise specified. Furthermore, some of members may be omitted or simplified in some of the drawings for the sake of clarity.

### 3.1 Configuration

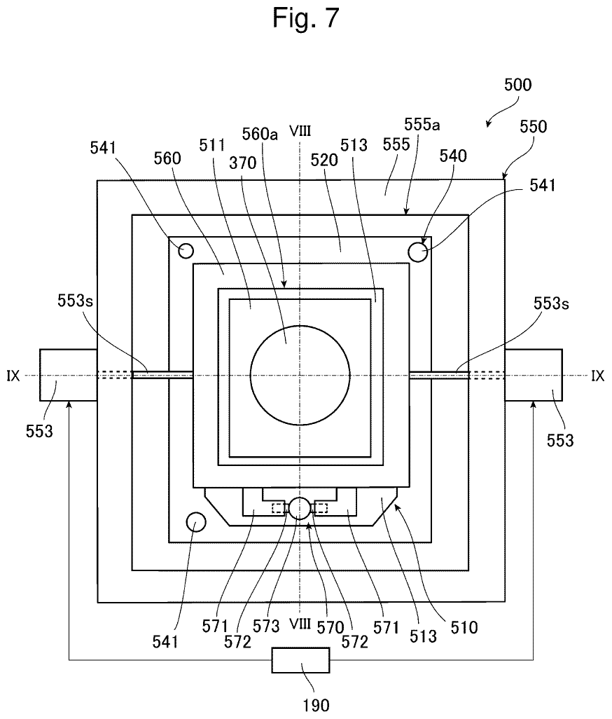

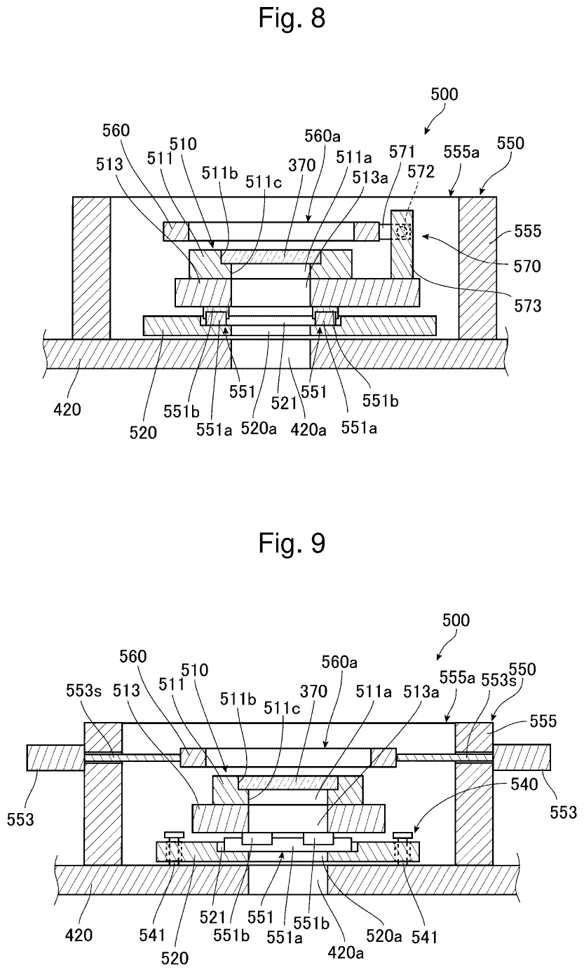

FIG. 7 is a front view of an output-side holding unit 500 of the present embodiment. FIG. 8 is a sectional view of the output-side holding unit 500 illustrated in FIG. 7 taken along the line VIII-VIII, and FIG. 9 is a sectional view of the output-side holding unit 500 illustrated in FIG. 7 taken along the line IX-TX.

The output-side holding unit 500 of the present embodiment is different from the output-side holding unit 500 of the comparative example in that the output-side holding unit 500 of the present embodiment includes a frame member 560 and an elastic connecting portion 570.

The frame member 560 is a member that is movable in a direction perpendicular to an optical axis of light output from a chamber device CH3, and includes an opening 560a. In the present embodiment, the shape of a frame member 560 is a rectangular frame shape. However, the shape of the frame member 560 may not be rectangular. Furthermore, a part of the frame member 560 may be cut off, and the shape of the frame member 560 may be a C shaped, for example. The frame member 560 is disposed on a side opposite to an output-side support member 420 side with reference to a holding portion 510, and an output coupling mirror 370 is exposed from an opening 560a of the frame member 560. Therefore, light incident on the output coupling mirror 370 and light reflected by the output coupling mirror 370 pass through the opening 560a. In the present embodiment, the opening 560a is larger than a main body portion 511 of the holding portion 510 and is smaller than an attachment plate 513. Therefore, the entire main body portion 511 is exposed from the opening 560a. In the present embodiment, a part of an outer peripheral portion of the attachment plate 513 overlaps the frame member 560, and the other part of the attachment plate 513 is located on the side further outward than an outer periphery of the frame member 560.

The frame member 560 is positioned between shafts 553s of a pair of cylinders 553. Therefore, in the present embodiment, the frame member 560 can move in the longitudinal direction of the shafts 553s by pushing and pulling of the shafts 553s.

The elastic connecting portion 570 includes a pair of arm portions 571, a pair of elastic members 572, and a pin member 573.

The pair of arm portions 571 each have a generally L shape, one end of each arm portion 571 is fixed to the outer peripheral surface of the frame member 560, and the other ends face each other. The elastic members 572 are disposed at the other ends of the arm portions 571, and a pair of elastic members 572 face each other. Examples of the elastic members 572 include coil springs and plungers. In the present embodiment, holes are formed at the other ends of the arm portions 571, parts of the elastic members 572 are inserted into the holes, and other parts of the elastic members 572 are exposed from the holes.

The pin member 573 is a columnar member fixed to the holding portion 510. In the present embodiment, the pin member 573 stands in a region of the attachment plate 513 located on the side further outward than the outer periphery of the frame member 560 and extends up to a position that is higher than the frame member 560. A side surface of the pin member 573 is positioned between the elastic members 572 to be pressed by the elastic members 572. Note that the pin member 573 may be a prismatic member.

### 3.2 Operation

When the shafts 553s of the cylinders 553 push and pull the frame member 560 in accordance with an instruction from the processor 190, the frame member 560 moves in a predetermined direction perpendicular to the optical axis of the light output from the chamber device CH3. Therefore, the arm portions 571 fixed to the frame member 560 moves, and the pin member 573 is pushed by the elastic members 572 to move in the direction in which the frame member 560 moves. The holding portion 510 to which the pin member 573 is fixed moves, and the output coupling mirror 370 moves, by the pin member 573 moving. Thus, the position of an irradiation spot S moves inside an effective region 370a in the output coupling mirror 370 as indicated by the dashed line in FIG. 6.

### 3.3 Effect and Advantage

The gas laser device 100 of the present embodiment includes a frame member 560 that is movable in the predetermined direction perpendicular to the optical axis of the light output from the chamber device CH3 and that includes an opening 560a from which the output coupling mirror 370 is exposed, a moving mechanism 550 that causes the frame member 560 to move, and an elastic connecting portion 570 that connects the holding portion 510 and the frame member 560 with an elastic force. Therefore, even in a case where the frame member 560 is deformed with a force applied from the moving mechanism 550 to the frame member 560, an influence of the deformation of the frame member 560 is absorbed by the elastic connecting portion 570, and deformation of the holding portion 510 can be suppressed. Therefore, it is possible to suppress a change in attachment angle of the output coupling mirror 370. Therefore, according to the gas laser device 100 of the present embodiment, laser light can be stably output.

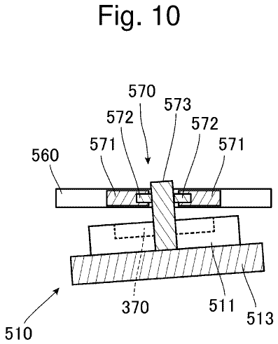

FIG. 10 is a diagram illustrating a state where the angle of the holding portion 510 has been adjusted. As illustrated in FIG. 10, even in a case where the angle of the output coupling mirror 370 is adjusted by the angle adjusting mechanism 540 adjusting the angle of the holding portion 510, an influence of the adjustment is absorbed by the elastic connecting portion 570. Specifically, one of the elastic members 572 extends and the other elastic member 572 contracts, for example. Thus, the deformation of the holding portion 510 or the frame member 560 can be suppressed through the adjustment of the angle of the holding portion 510.

Furthermore, in the present embodiment, the elastic connecting portion 570 includes the pin member 573 fixed to the holding portion 510, the pair of arm portions 571 fixed to the frame member 560, and the pair of elastic members 572 provided in the respective arm portions 571 and positioned on the respective sides of the pin member 573 in a predetermined direction. With this configuration, the connection to the holding portion 510 is unlikely to be released even in a case where the frame member 560 is distorted in a surface direction.

Note that although the arm portions 571 are fixed to the outer peripheral surface of the frame member 560 in the present embodiment, the arm portions 571 may be fixed to a place other than the outer peripheral surface of the frame member 560. The arm portions 571 may not each have the L shape as long as the elastic members 572 are provided, and may each have a columnar shape, for example.

### 4. Description of Gas Laser Device of Second Embodiment

Next, a gas laser device 100 of a second embodiment will be described. Note that configurations similar to the configurations described above will be denoted by the same reference signs, and repeated description will be omitted unless otherwise specified. Furthermore, some of members may be omitted or simplified in some of the drawings for the sake of clarity.

### 4.1 Configuration

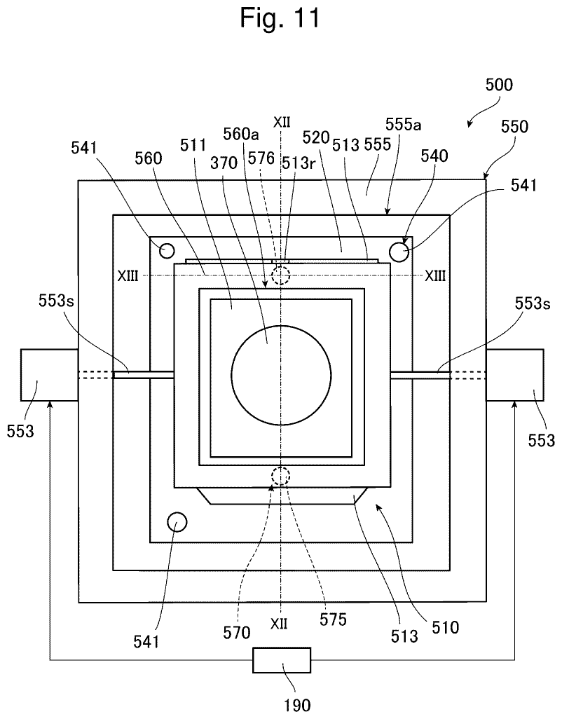

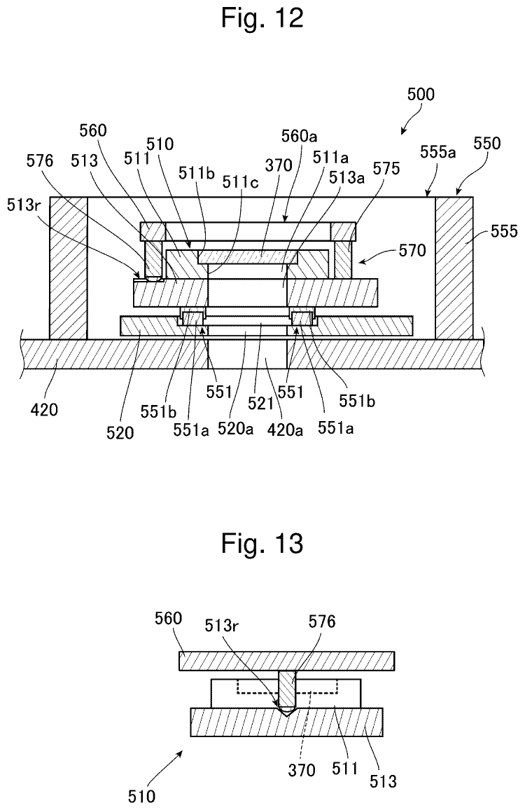

FIG. 11 is a front view of an output-side holding unit 500 of the present embodiment, and FIG. 12 is a sectional view of the output-side holding unit 500 illustrated in FIG. 11 taken along the line XII-XII.

In the output-side holding unit 500 of the present embodiment, a configuration of an elastic connecting portion 570 is different from the configuration of the elastic connecting portion 570 of the first embodiment. The elastic connecting portion 570 of the present embodiment includes a restraining member 575 and a support member 576.

The support member 576 is provided on a bottom surface that is a surface of a frame member 560 on a side of a holding portion 510. Specifically, the support member 576 is provided at a position where the support member 576 overlaps with an attachment plate 513 on the bottom surface of the frame member 560. The support member 576 is composed of, for example, a plunger screw. The plunger screw is provided with a coil spring inside a tubular member and a ball or a pin with a round distal end and is configured to be movable in a state where the ball or the pin is pressed by the coil spring in the longitudinal direction of the tubular member.

FIG. 13 is a sectional view of the output-side holding unit 500 illustrated in FIG. 11 taken along the line XIII-XIII. However, FIG. 13 illustrates only the holding portion 510, the frame member 560, and the support member 576. As illustrated in FIG. 13, the attachment plate 513 of the present embodiment is provided with a recessed portion 513r. In the example of FIG. 13, the recessed portion 513r is a V-shaped groove. The longitudinal direction of the V-shaped groove extends in a direction perpendicular to a predetermined direction in which the frame member 560 moves. Note that the recessed portion 513r may be a weight-shaped depression. A part of the support member 576 is placed inside the recessed portion 513r. For example, in a case where the support member 576 is composed of a plunger screw as described above, a ball or a pin of the plunger screw are placed inside the recessed portion 513r. Therefore, in a case where the support member 576 moves in a predetermined direction, an inclined surface of the V-shaped groove is pressed in the predetermined direction by the support member 576.

The restraining member 575 is provided at a position where the restraining member 575 overlaps with the attachment plate 513 on the bottom surface of the frame member 560 and is fixed to the holding portion 510 and the frame member 560. In this example, the restraining member 575 has a columnar shape, one end is fixed to the holding portion 510, and the other end is fixed to the frame member 560. In the present embodiment, the support member 576 and the restraining member 575 are positioned on the respective sides across the output coupling mirror 370 in a front view of the output coupling mirror 370. Furthermore, in the present embodiment, the support member 576 and the restraining member 575 are provided at symmetrical positions with reference to a central axis of shafts 553s of cylinders 553. The restraining member 575 is formed of a material having a high elastic constant and presses the support member 576 against the holding portion 510 via the frame member 560 with an elastic force. In other words, the restraining member 575 includes an elastic member having an elastic force in a direction in which the support member 576 is pressed against the attachment plate 513 of the holding portion 510. In addition, in a case where the support member 576 is a plunger screw as described above, the support member 576 has a spring that presses a ball or a pin inside, and the support member 576 thus includes an elastic member that has an elastic force in the direction in which the support member 576 is pressed against the attachment plate 513 of the holding portion 510. Note that although the support member 576 may be composed of a member other than a plunger screw, the support member 576 preferably includes an elastic member having such an elastic force. In this example, the length of the support member 576 is longer than that of the restraining member 575 by the amount corresponding to the entrance into the recessed portion 513r in the direction directed from the frame member 560 to the attachment plate. When the frame member 560 moves in the predetermined direction because the restraining member 575 presses the support member 576 against the holding portion 510, the support member 576 presses the side surface of the recessed portion 513r in the predetermined direction.

### 4.2 Operation

Similarly to the first embodiment, the shafts 553s of the cylinders 553 push and pull the frame member 560, such that the frame member 560 moves in the predetermined direction. Therefore, the support member 576 presses the side surface of the recessed portion 513r in the predetermined direction. The side surface is an inclined surface in a case where the recessed portion 513r is a V-shaped groove or a weight-shaped depression. As described above, the force caused by the movement of the frame member 560 is transmitted to the holding portion 510. The restraining member 575 also transmits the force caused by the movement of the frame member 560 to the holding portion 510. Therefore, the holding portion 510 moves, and the output coupling mirror 370 moves.

### 4.3 Effect and Advantage

In the present embodiment, the holding portion 510 includes the recessed portion 513r provided on the side of the frame member 560, and the elastic connecting portion 570 includes the support member 576 fixed to the frame member 560 and partially placed inside the recessed portion 513r and the restraining member 575 fixed to the holding portion 510 and the frame member 560 and pressing the support member 576 against the holding portion 510. Therefore, since the holding portion 510 is caused to move by the support member 576 and the restraining member 575 applying a force to the holding portion 510, it is possible to cause the holding portion 510 to stably move.

### 5. Description of Gas Laser Device of Third Embodiment

Next, a gas laser device 100 of a third embodiment will be described. Note that configurations similar to the configurations described above will be denoted by the same reference signs, and repeated description will be omitted unless otherwise specified. Furthermore, some of members may be omitted or simplified in some of the drawings for the sake of clarity.

### 5.1 Configuration

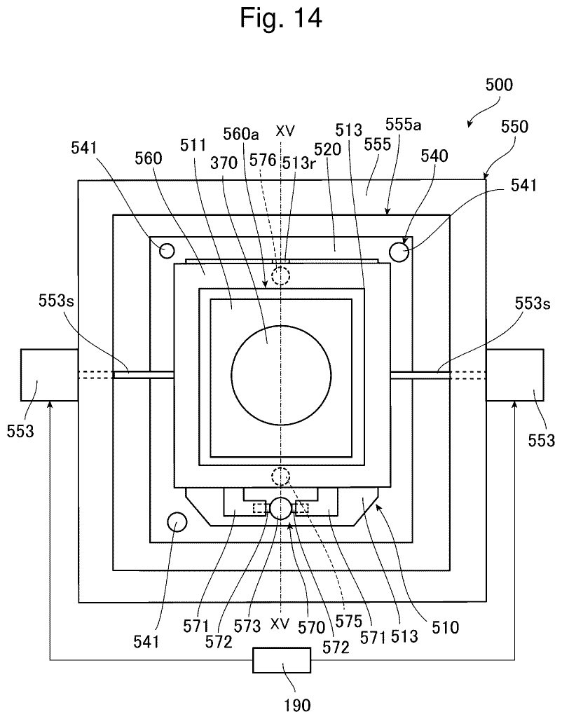

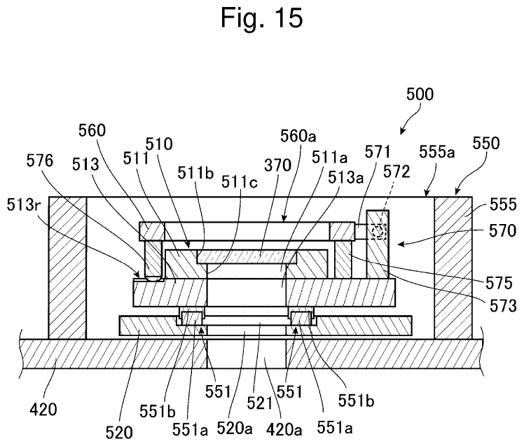

FIG. 14 is a front view of an output-side holding unit 500 of the present embodiment. FIG. 15 is a sectional view of the output-side holding unit 500 illustrated in FIG. 14 taken along the line XV-XV. In the gas laser device 100 of the present embodiment, an elastic connecting portion 570 includes the configuration of the elastic connecting portion 570 of the first embodiment and the configuration of the elastic connecting portion 570 of the second embodiment. Therefore, a holding portion 510 of the present embodiment has a recessed portion 513r inside which a part of a support member 576 is placed.

### 5.2 Operation

Similarly to the first embodiment, shafts 553s of cylinders 553 push and pull a frame member 560, such that the frame member 560 moves in a predetermined direction. In the present embodiment, arm portions 571 move, and a pin member 573 pushed by elastic members 572 moves in a direction in which the frame member 560 moves, similarly to the first embodiment. Furthermore, a support member 576 presses a side surface of the recessed portion 513r in a predetermined direction, and the restraining member 575 also transmits a force caused by the movement of the frame member 560 to the holding portion 510, similarly to the second embodiment. Therefore, the holding portion 510 moves, and an output coupling mirror 370 moves.

### 5.3 Effect and Advantage

In the present embodiment, the elastic connecting portion 570 includes a pin member 573 fixed to the holding portion 510, a pair of arm portions 571 fixed to the frame member 560, a pair of elastic members 572 provided in the respective arm portions 571 and positioned on the respective sides of the pin member 573 in the predetermined direction, a support member 576 fixed to the frame member 560 and partially placed inside the recessed portion 513r, and a restraining member 575 fixed to the holding portion 510 and the frame member 560 and pressing the support member 576 against the holding portion 510. Therefore, as compared with the first embodiment and the second embodiment, the force caused by the movement of the frame member 560 is transmitted to the holding portion 510 from more places. Therefore, the holding portion 510 can be stably moved.

The configurations of the output-side holding units 500 of the first to third embodiments may be applied to the rear-side holding unit 600.

The description above is intended to be illustrative and the present disclosure is not limited thereto. Therefore, it would be obvious to those skilled in the art that various modifications to the embodiments of the present disclosure would be possible without departing from the spirit and the scope of the appended claims. Further, it would be also obvious to those skilled in the art that embodiments of the present disclosure would be appropriately combined. The terms used throughout the present specification and the appended claims should be interpreted as “non-limiting” terms, unless otherwise specified. For example, terms such as “comprise”, “include”, “have”, and “contain” should be interpreted to be “not exclusive of components other than the described components”. Furthermore, modifiers “a/an” should be interpreted to mean “at least one” or “one or more”. Furthermore, “at least one of A, B, and C” should be interpreted to mean any of “A”, “B”, “C”, “A+B”, “A+C”, “B+C”, and “A+B+C” as well as to include combinations of any of them and components other than A, B, and C.

What is claimed is:

1. A gas laser device comprising:
a chamber device including an electrode inside the chamber device in which a laser gas is sealed, the chamber device being configured to output, to outside through a window, light generated from the laser gas by a voltage being applied to the electrode;
a mirror disposed outside the chamber device and configured to reflect a part of the light output from the chamber device;
a holding portion holding the mirror and configured to be movable in a predetermined direction perpendicular to an optical axis of the light;
a frame member configured to be movable in the predetermined direction and including an opening from which the mirror is exposed;
a moving mechanism configured to cause the frame member to move; and
an elastic connecting portion configured to connect the holding portion and the frame member with an elastic force.

2. The gas laser device according to claim 1, further comprising:
an angle adjusting mechanism configured to be able to adjust an angle of the mirror with respect to the optical axis.

3. The gas laser device according to claim 1, further comprising:
a base member movably holding the holding portion, wherein
the moving mechanism includes a slide guide provided between the base member and the holding portion and configured to allow the holding portion to move in the predetermined direction with respect to the base member.

4. The gas laser device according to claim 1, wherein the moving mechanism includes a pair of cylinders with shafts positioned on respective sides of the frame member in a moving direction.

5. The gas laser device according to claim 1, wherein the elastic connecting portion includes a pin member fixed to the holding portion, a pair of arm portions fixed to the frame member, and a pair of elastic members provided in the respective arm portions and positioned on respective sides of the pin member in the predetermined direction.

6. The gas laser device according to claim 5, wherein the arm portions are fixed to an outer peripheral surface of the frame member.

7. The gas laser device according to claim 1, wherein
the holding portion includes a recessed portion provided on a side of the frame member, and
the elastic connecting portion includes a support member fixed to the frame member and partially placed inside the recessed portion and a restraining member fixed to the holding portion and the frame member and pressing the support member against the holding portion.

8. The gas laser device according to claim 7, wherein the support member and the restraining member are positioned on respective sides across the mirror in a front view of the mirror.

9. The gas laser device according to claim 7, wherein
the moving mechanism further includes a pair of cylinders with shafts positioned on respective sides of the frame member in a moving direction, and
the support member and the restraining member are provided at symmetrical positions with respect to a central axis of the shafts.

10. The gas laser device according to claim 7, wherein the recessed portion is a V-shaped groove with a longitudinal direction extending in a direction perpendicular to the predetermined direction.

11. The gas laser device according to claim 7, wherein the support member includes an elastic member having an elastic force in a direction in which the support member is pressed against the holding portion.

12. The gas laser device according to claim 1, wherein
the holding portion includes a recessed portion provided on a side the frame member, and
the elastic connecting portion includes a pin member fixed to the holding portion, a pair of arm portions fixed to the frame member, a pair of elastic members provided in the respective arm portions and positioned on respective sides of the pin member in the predetermined direction, a support member fixed to the frame member and partially placed inside the recessed portion, and a restraining member fixed to the holding portion and the frame member and pressing the support member against the holding portion.

13. An electronic device manufacturing method comprising:
generating laser light with a gas laser device, the gas laser device including
a chamber device including an electrode inside the chamber device in which laser gas is sealed, the chamber device being configured to output, to outside through a window, light generated from the laser gas by a voltage being applied to the electrode,
a mirror disposed outside the chamber device and configured to reflect a part of the light output through the window,
a holding portion holding the mirror and configured to be movable in a predetermined direction perpendicular to an optical axis of the light,
a frame member configured to be movable in the predetermined direction and including an opening from which the mirror is exposed,
a moving mechanism configured to cause the frame member to move, and
an elastic connecting portion configured to connect the holding portion and the frame member with an elastic force;
outputting the laser light to an exposure device; and
exposing a photosensitive substrate to the laser light inside the exposure device to manufacture an electronic device.
